(19) United States
(12) Patent Application Publication
(10) Pub. No.: US 2025/0391439 A1
(43) Pub. Date: Dec. 25, 2025

(54) TOP-LOADING DRIVE CADDY AND GUIDEWAY MOUNTING

(71) Applicant: Zoho Corporation Private Limited, Kanchipuram District (IN)

(72) Inventors: Yash Manoj Kadu, Nagpur (IN); Mangesh Devidas Sadafale, Nagpur (IN)

(73) Assignee: Zoho Corporation Private Limited, Kanchipuram District (IN)

(21) Appl. No.: 19/213,454

(22) Filed: May 20, 2025

Related U.S. Application Data
(60) Provisional application No. 63/682,947, filed on Aug. 14, 2024.
(60) Provisional application No. 63/682,960, filed on Aug. 14, 2024.

(30) Foreign Application Priority Data
Jun. 25, 2024 (IN) 202441048667
Jun. 26, 2024 (IN) 202441049035

(51) Int. Cl. G11B 33/12; H05K 7/14

(52) U.S. Cl. CPC G11B 33/128; H05K 7/1418

(57) ABSTRACT

A top-loading drive caddy has a body comprising a crossmember with a first and second grip on opposing sides, a stopping edge, and first and second guiding sides having first and second widths extending from the crossmember to connect to the storage drive with one or more mounting pins. A stopping edge extends from a guiding side placed to determine the location of the drive. A guideway receiving the caddy comprises notches on first and second sides extending transversely from top to bottom of an elongated body, the notches spaced apart to engage the guiding sides. A guideway assembly comprises a plurality of the caddy and two or more of the guideways, parallel to each other with aligned notches, the guideways separated to allow caddies to be inserted with guiding sides engaging notches on at least two of the guideways.

### CROSS REFERENCE TO RELATED APPLICATIONS

This application is related to Indian Provisional Application 202441048667, filed 25 Jun. 2024, and U.S. Provisional Application 63/682,947 filed 14 Aug. 2024, both entitled “TOP-LOADING DRIVE CADDY AND GUIDEWAY MOUNTING”, both of which are incorporated herein by reference.

This application is also related to Indian Provisional Application 202441049035, filed 26 Jun. 2024, and U.S. Provisional Application 63/682,960 (hereinafter the '960 application), filed 14 Aug. 2024, both entitled “DIRECT RAPID AIR-COOLING SYSTEM FOR SERVER CADDY ARRAYS”, both of which are incorporated herein by reference.

### FIELD OF THE INVENTION

Embodiments of the present disclosure are related, in general, to data servers and more particularly, but not exclusively, to drive caddies.

### BRIEF DESCRIPTION OF THE DRAWINGS

The subject matter disclosed is illustrated by way of example, and not by way of limitation, in the figures of the accompanying drawings and in which like reference numerals refer to similar elements and in which:

FIGS. 1A-1D depict a drive caddy 10 that receives and supports a storage drive.

FIG. 2 depicts a guideway 40, which is compatible with caddies 10.

FIGS. 3A-3H illustrate the use of caddies 10 and guideways 40 in a guideway assembly 70.

FIG. 4 illustrates caddies 10 and guideways 40 in an example server chassis.

### DETAILED DESCRIPTION

Drive caddies, also known as drive trays or drive carriers, are essential components in server environments. They are used to house and secure hard drives (HDDs) or solid-state drives (SSDs), collectively “storage drives” or just “drives,” in a server chassis. Many servers support hot-swappable drives, allowing drives to be replaced or added without powering down the server.

Drive caddies are available for different form factors, typically 2.5-inch and 3.5-inch drives, matching the common sizes of HDDs and SSDs. By using appropriate drive caddies, server administrators can efficiently manage storage devices, ensuring reliability, ease of maintenance, and scalability in their server environments.

A server chassis can be configured to house sets of caddies and can be customized to take advantage of the design features of the caddy.

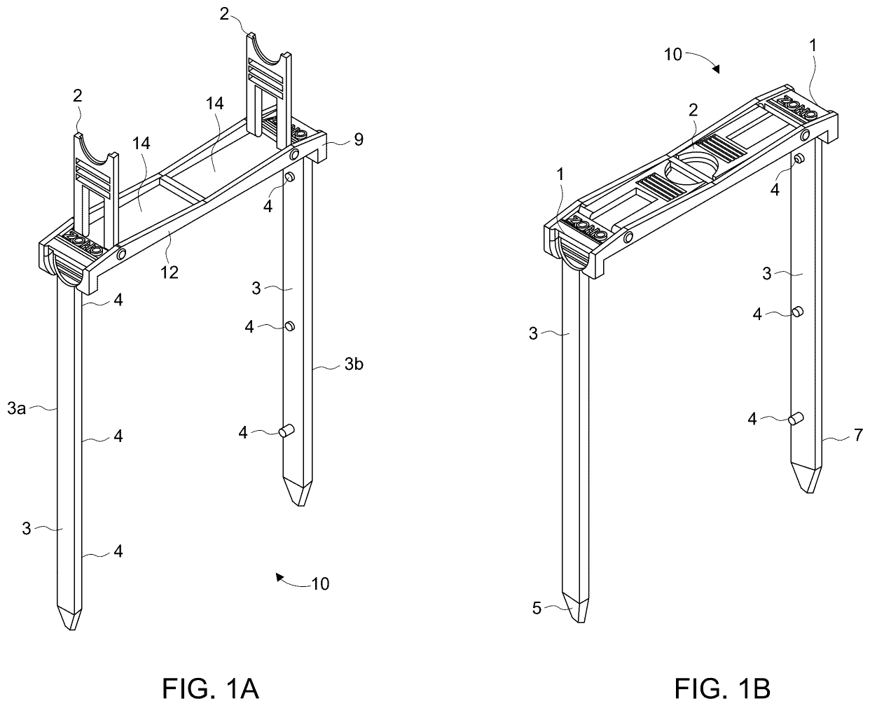

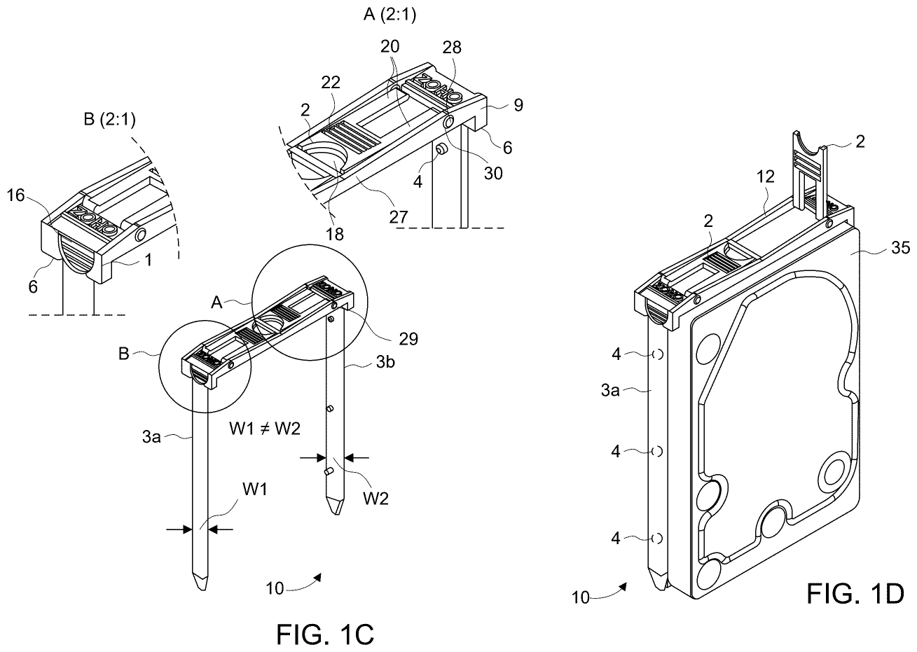

FIGS. 1A-1D depict a drive caddy 10 that receives and supports a storage drive. One or more such drive caddies can be installed in a computer system, such as a server. The caddy is adapted to be inserted into a top-loading server chassis. Its unidirectional hot-swap screwless design allows it to be inserted into the chassis achieving correct alignment, avoiding incorrect guiding which can lead to physical damage, data loss, and hardware failure. The caddy is a protective robust enclosure which safeguards the drive from physical damage. It is designed for hot swapping which reduces maintenance costs by minimizing the need for system shutdowns. The need for additional tools or locking mechanisms is eliminated, reducing overall equipment costs.

FIG. 1A shows caddy 10 comprising three parts: a caddy body 9 and two handles 2. The caddy body 9 comprises a crossmember 12 and two sides 3 which also serve as guides 3a and 3b. The handles 2 are depicted in the extended, or open, position, outside of handle receptacles 14. FIG. 1B shows caddy 10 with the handles 2 closed into handle receptacles 14. Caddy body 9 and each handle 2 are of unitary construction, which is to say they are each made of a single piece of material. The pieces can be injection molded from plastic or can be formed using alternate means and using alternate materials. Recycled plastic minimizes environmental impact and can be more cost-effective than standard materials. The use of plastic in an example embodiment reduces overall weight of the caddy.

Mounting pins 4 extend inwardly from the guides and are located such that the flexible guides 3a and 3b can be extended outward to allow a drive 35 to be inserted into the caddy as shown in FIG. 1D. The mounting pins 4 are located on the guides such that they can engage with one or more cavities, e.g. the screw holes (not shown), of the drive 35. The drive is then secure in the caddy, with the two sides or guides 3 and the cross member 12 surrounding it. Thus, this screw-free mechanism is integrated into a protective enclosure for the drive. A user can easily attach and detach a drive with nominal force via the mounting pins 4 provided, which align with drive holes with precision. The screwless design reduces cost, reduces time required to insert hard drives, and removes the dependency on manufacturing from other countries, should parts such as screws be unavailable domestically.

The handles 2 facilitate hot swapping. the handles can be extended or retracted into open or closed formations. When extended or open, the handles 2, grooved for gripping in this embodiment, can be grasped and used to pull the caddy up and out of a server chassis. Hot swapping without handles 2 is supported, using only nominal force from a user's fingers. Grips 1 are provided for this purpose and can be grooved or have alternate texturing to provide friction for handling. The ends of the guides 3a and 3b are tapered (5) and the edges are filleted (7) for easy and smooth insertion of the caddy into guideways (detailed below) and for smooth removal as well.

FIG. 1C further illustrates the handles 2, each of which comprises flexible members 20 with pins 28 fixed to the end. A pivot point 29 is defined by holes 30 in sidewalls 27 of the handle receptacles. The flexible members 20 can be pinched together to allow the pins 28 to be aligned with the holes 30 and released to secure each handle in place. A cutout 18 on the handle edge allows for the handle to be easily accessed and extended from a closed position. A handle grip 22, formed by texture on each side of the handle in this embodiment, ensures friction to prevent slippage when the handle is being pulled.

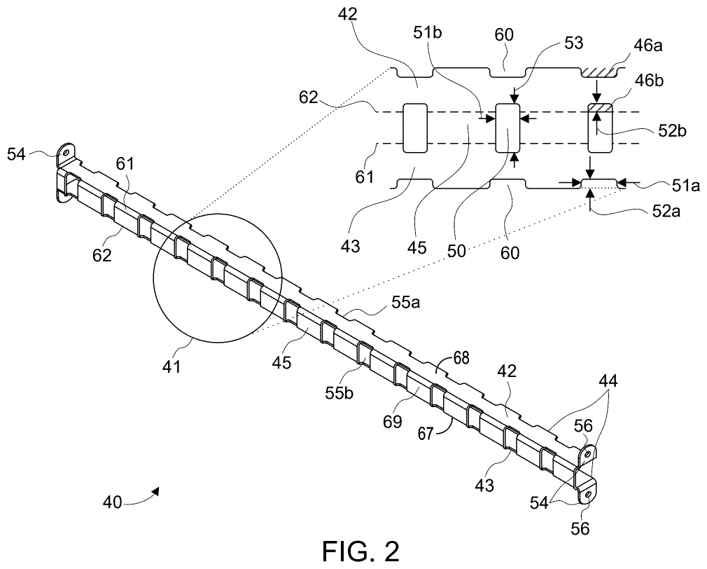

Unidirectional guiding is implemented when both sides 3 differ in width. In FIG. 1C, one side, or guide 3a, has width W1. The other guide 3b has width W2. W1 is not equal to W2 in the example embodiment. A compatible guideway 40 is introduced in FIG. 2 allowing the caddy to be inserted into a chassis in only one orientation. The differing widths of 3a and 3b will prevent the caddy being inserted in an alternate orientation. Unidirectional guide is one feature in the example embodiment, but it is not mandatory. Caddies and guides can have the same size on each side.

FIG. 1C further illustrates the location of grips 1 on each end of the crossmember 12, which can be simultaneously gripped to insert or remove a caddy from a chassis. A texture such as grooves 16 can be added to facilitate secure gripping.

At least one caddy stop 6 is formed by an overhang of crossmember 9 relative to an edge of a side 3 defining the stopping edge, or caddy stop 6. As shown in FIG. 1C, the example embodiment has stopping edges 6 on both ends of the crossmember 9. These automatically secure the drive and caddy in place while top loading without the need for any additional locking mechanism. They come to rest on a rail such as a guideway 40 (detailed below). When top-loading, the caddy 10 is inserted straightforwardly in the guideways 40. The user first places the drive into the caddy, ensuring proper alignment with the mounting pins 4 and unidirectional guides 3a and 3b, as shown in FIG. 1D. Then, as the caddy 10 containing the drive 35 is inserted, it is automatically secured in place by stopping edges 6, preventing caddy over-insertion, without the need for any additional locking mechanism. The screwless and springless mechanism ensures that the drive is firmly held within the caddy, providing stable and correct positioning. This tool-free insertion process not only simplifies the task but also reduces the risk of physical damage or data loss during drive swaps.

FIG. 2 depicts the example embodiment of a guideway 40, which is compatible with caddies 10 just described. A guideway 40 is operable with a top-loading caddy 10 having a first guide 3a with a first width and a second guide 3b with a second width. The guideway 40 comprises an elongated body 41 extending along a longitudinal axis, the elongated body 41 having a top surface 42, a bottom surface 43, a first side 44, and a second side 45 opposite the first side 44. A plurality of first notches 55a are formed in the first side 44 of the elongated body 41, each first notch 55a extending transversely from the top surface 42 to the bottom surface 43 and being spaced apart along the longitudinal axis, wherein each notch defines a first contour 46a visible in a top view or a bottom view of the elongated body 41, and wherein each first notch 55a is configured to engage with the first guide 3a, the first contour 46a being shaped to receive the first guide 3a. A plurality of second notches 55b are formed in the second side 45 of the elongated body 41, each second notch 55b extending transversely from the top surface 42 to the bottom surface 43 and being spaced apart along the longitudinal axis, each second notch 55b being aligned with a respective first notch 55a, wherein each second notch 55b defines a second contour 46b visible in a top view or a bottom view of the elongated body 41, and wherein each second notch 55b is configured to engage with the second guide 3b, the second contour 46b of each second notch being shaped to receive the second guide 3b.

The example embodiment of guideway 40 in FIG. 2 has the elongated body 41 formed from a sheet of metallic material bent along the longitudinal axis to define a C-shaped cross-section, the C-shaped cross-section comprising a central web portion 69 connecting two opposing flange portions 67 and 68, wherein the top surface 42 and the bottom surface 43 are defined by upper and lower edges of the central web portion and the top and bottom surfaces of the two opposing flange portions, respectively. First side 44 is defined by outer edges of the two opposing flange portions (67 and 68), the plurality of first notches 55a being formed along the outer edges of the two opposing flange portions. The second side 45 is defined by the central web portion 69 further comprising a plurality of cutouts 50 formed through the central web portion 69 and the two opposing flange portions (67 and 68), each cutout 50 being aligned with a respective first notch 55a, each cutout, once bent, forming one of the plurality of second notches 55b, the second contour 46b defined by a portion of the respective cutout formed in one of the two opposing flange portions.

The top 42 and bottom 43 both have, as a mounting apparatus, brackets 54, which include holes 56 for attaching the guideway to a server chassis. Notches or channels 55 are shown on both sides, which are designed to receive guides 3 of a caddy 10. Notches 55a are sized to receive guides 3a and notches 55b are sized to receive guides 3b. The notches forming channels/notches 55 are filleted.

The C shape of guideway 40 is formed by bending along fold lines 61 and 62. A flat cutout (pre-bend) is shown to illustrate the formation of the notches 55. Notches 55b are formed by introducing cutouts 50 in the pre-folded guideway. Note that the width 51b and notch depth 52b of the cutout 50 is selected to accommodate the width W2 and at least a portion of the thickness of guide 3b plus any tolerance. Notch depths 52b indicate the desired channel depth for receiving guides in notches 55b, determined according to the differences between the top and bottom edges of cutout 50 and fold lines 62 and 61, respectively. The height 53 of the cutout 50 is sized to accommodate the height of the side 45 of the guideway, once folded, plus two notch depths 52b. Notches 55a are formed with a pair of aligned flange notches 60, one from the top flange 67 and one from the bottom flange 68, once the guideway is folded, as shown. The width 51a and depth of notches 60 are designed to comfortably accommodate guides 3a of width W1 plus any tolerance. Using a flange notch pair is optional. A single flange notch may be utilized, so long as the other flange is designed so as not to obstruct the engagement of a guide into the single flange notch.

A C-shape for guideway 40 is selected for a balance of strength and cost-effectiveness. Alternative embodiments could use I-shapes, square beams, or others. These alternates would be adapted to provide a resting edge for stops 6, may have an additional side in which notches 55a would be cut, and other adaptations by those of ordinary skill in the art.

A guideway assembly comprises a plurality of caddy 10 and two or more of the guideways 7. A guideway assembly includes a first guideway and a second guideway parallel to each other and having the first and second plurality of notches of each of the first and second guideways aligned, separated by a distance allowing for a caddy to be inserted into the guideway assembly such that the first guiding side of the caddy engages with one of the first plurality of channels of the first guideway and the second guiding side of the caddy engages with an aligned one of the second plurality of channels of the second guideway.

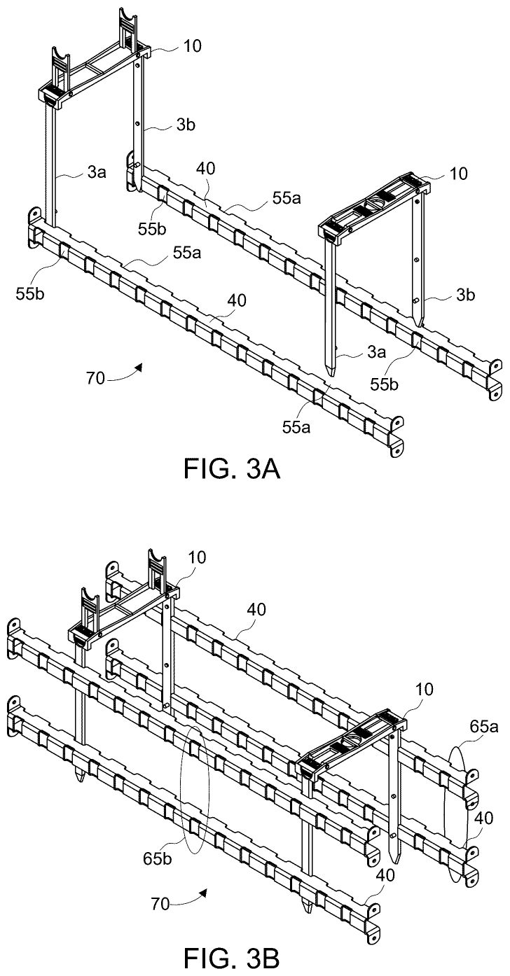

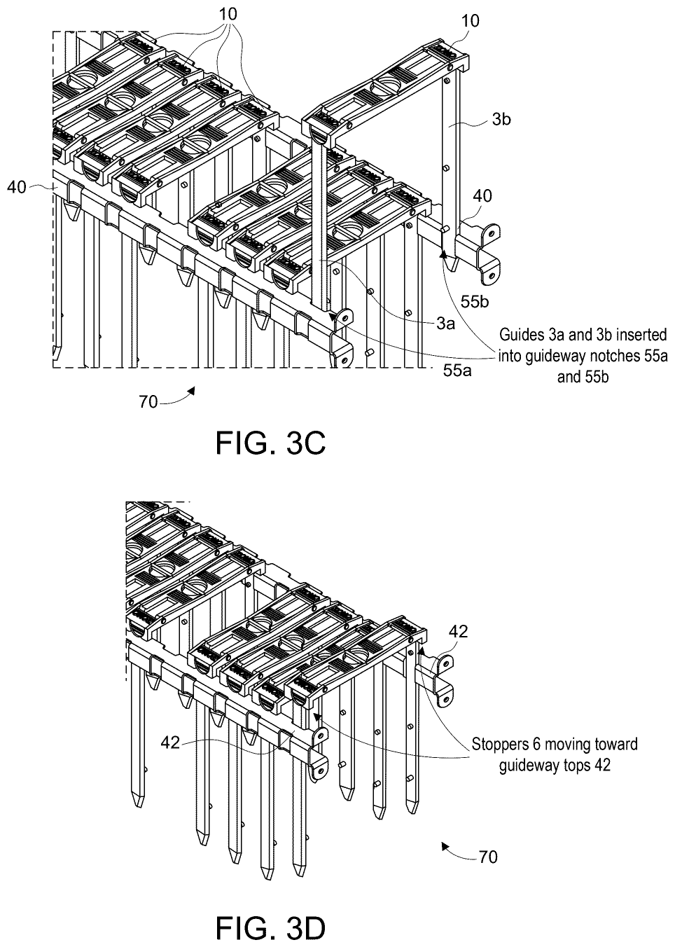

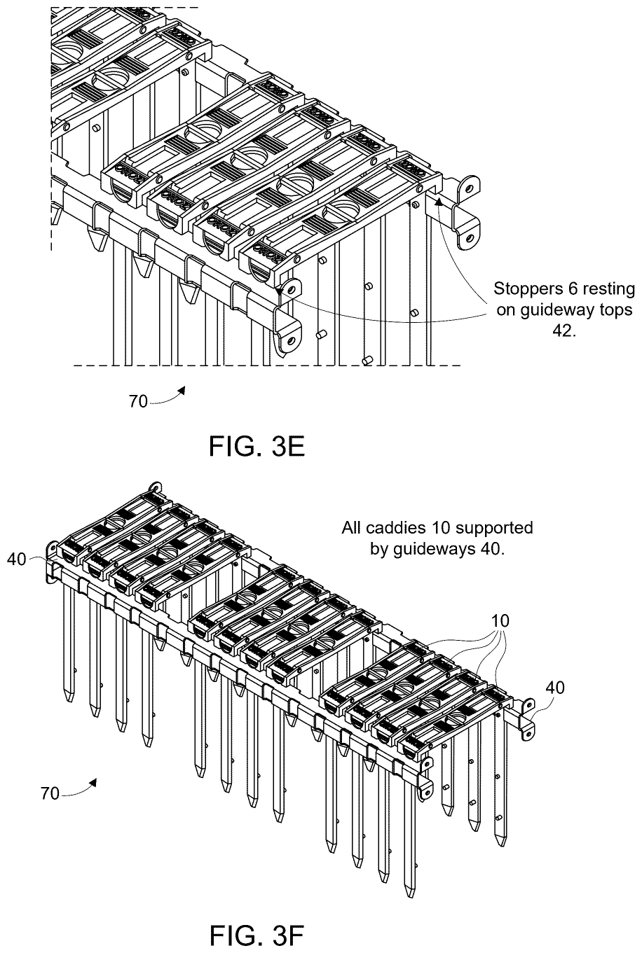

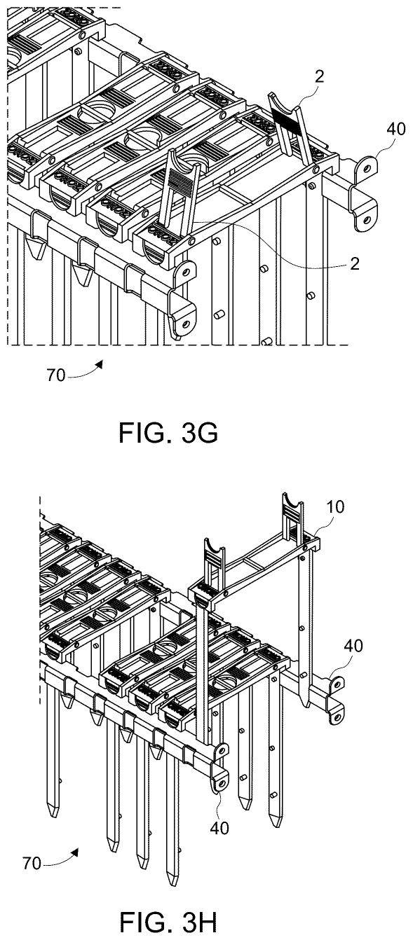

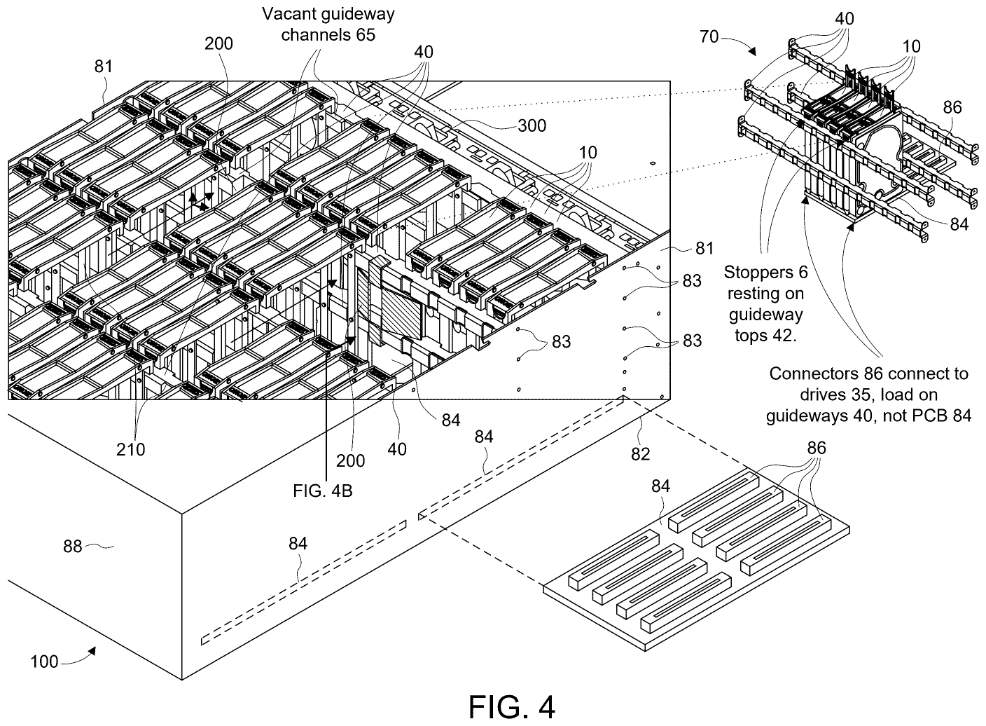

FIGS. 3A-3H illustrate the use of caddies 10 and guideways 40 in a guideway assembly 70. Guideway assemblies 70 may have any number of guideways 40 and caddies 10, and may be incorporated in a server chassis, as illustrated in an example embodiment in FIG. 4. In these examples, each guideway 40 supports one side of a row of 14 drive caddies 10. The number of notches and channels can be modified to support different numbers or sizes of caddies in alternate embodiments. To support a single row of caddies 10, two guideways 40 are deployed (or sets of guideways, detailed below). To support an additional row of caddies 10, a single guideway 40 (or set) is added. The total number of guideways 40 (which can advantageously all be identical) required to support N rows of caddies is N+1, thus optimizing space in the server chassis. FIG. 4 illustrates an embodiment with 5 sets of guideways supporting 4 rows of caddies.

In FIG. 3A two caddies 10 are shown beginning insertion in two guideways 40. These caddies are empty, for illustrative purposes. A guideway assembly may receive any combination of empty or drive-loaded caddies 10. A first caddy 10 at the right of the guideway assembly 70, with handles 2 closed, is poised just above the guideways 40. Its guide 3a is poised to enter its respective notch 55a. Its guide 3b is poised to enter its respective notch 55b. Note that if the orientation is changed, the caddy will not be able to be inserted, as at least one guide will be larger than its channel, since W1 is not equal to W2 by design. The second caddy 10 at the left of guideway assembly 70, with handles 2 open, has just begun insertion in the guideways 40, with guides 3a and 3b engaging notches 55a and 55b, respectively.

A guideway assembly can further comprise sets of guideways aligned vertically, having their notches aligned, both within the set of guideways, and with a parallel set of guideways. The sets are separated by a distance allowing for a caddy to be inserted into the guideway assembly such that the first guiding side of the caddy engages with one of the first plurality of channels formed in one set and the second guiding side of the caddy engages with an aligned one of the second plurality of channels formed in a second set.

FIG. 3B illustrates the guideway assembly 70 of FIG. 3A, comprising 4 guideways 40. While only two are required, as illustrated in FIG. 3A, alternate embodiments may include an additional row for a variety of reasons, such as additional chassis structural support. The assembly 70 of FIG. 3B will be used in the example illustrated in FIG. 4. The other FIGS. 3A and 3C-3H show only the top two guideways 40. A channel 65 includes one or more aligned notches. Here a plurality of channels 65a are formed, each channel 65a comprising two aligned notches 55a. Similarly, a plurality of channels 65b are formed, each channel 65b comprising two aligned notches 55b. When a single row of guideways is deployed, as in FIG. 3A, a channel 65a is a single notch 55a, and a channel 65b is a single notch 55b. Here the caddies 10 described above have had continued, but not quite complete, insertion into the guideway assembly 70. Each caddy's guideways 3a and 3b have engaged with the respective channels 65a and 65b of both the top and bottom sets of guideways 40. The insertion is not complete since the stopping edge 6 of either caddy crossmember 12 has not engaged with the top of at least one guideway 40.

FIG. 3C shows the last of a set of caddies 10 being inserted into a guideway assembly 70. Here the guides 3a and 3b have been inserted into the respective channels 65a and 65b. Three other caddies are shown fully inserted, contiguous with the caddy being inserted. Another bank of four caddies 10 is also inserted into the guideway assembly 70, with a slot for a caddy left vacant in between the two banks of caddies. FIG. 3D illustrates the caddy 10 as it is being inserted, approaching its final position, and stoppers 6 are moving toward the tops 42 of each guideway 40. FIG. 3E illustrates the caddy 10 fully inserted, with its stoppers 6 resting on the guideway tops 42. FIG. 3F shows each of 3 banks of caddies 10 fully inserted, each supported by guideways 40, with a vacant slot between each set of banks. This example configuration allows additional airflow between the sets of banks, facilitated by the vacancies.

FIGS. 3G and 3H illustrate removing a caddy 10 via its handles 2. Note that alternatively it could be removed by grasping the grips 1, not shown. The handles 2 are opened as shown in FIG. 2. They can be grasped, and the caddy easily pulled upwards. The caddy 10 nearly removed is illustrated in FIG. 3H.

FIG. 4 illustrates caddies 10 and guideways 40 in an example server chassis, in this case illustrated as a drawer 100. Server chassis drawer 100 has two sides 81 and a front 88 shown. The additional processing components and the back of the drawer are not shown for simplicity. Guideways 40 are attached to each side 81 via attachments 83. In this example, attachments 83 are machined screw holes, which allow screws (not shown) to be inserted through holes 56 and screwed into those attachment holes. The caddies in the main portion of the figure are shown inserted without drives to allow visibility to the other components, such as Printed Circuit Boards (PCBs) 84 shown attached to the drawer bottom 82 (positions illustrated by hidden lines identifying two rows of PCBs 84).

In this example, each PCB accepts 4 drives (in caddies) from one row and 4 drives (in caddies) from a neighboring row. Each PCB 84 has 8 HDD connectors 86 as shown. The PCBs will be connected to the server components (details not shown). In this configuration, there are 4 rows of 12 caddies for a total of 48 drives. 5 sets of two guideways 40 are utilized, 3 in the middle of the rows, and two on the ends. Airflow channels are formed by leaving vacant some of the channels 65 on the sets of guideways 40. Airflow is also possible through the caddies as well.

An example guideway assembly 70 (described above) is shown with caddies 10 including drives 35. As shown, the caddies 10 are inserted with stoppers 6 resting on guideway tops 42 of the top guideways 40. The drives are connected to the PCB 84 through connectors 86, but the load is on the guideways 40, not PCB 84.

Also shown in FIG. 4 are fans 300, air-diversion devices 200, and air flow channels 210. These are detailed fully in the aforementioned '960 application, incorporated by reference herein.

The foregoing description of the implementations of the present techniques and technologies has been presented for the purposes of illustration and description. This description is not intended to be exhaustive or to limit the present techniques and technologies to the precise form disclosed. Many modifications and variations are possible in light of the above teaching. It is intended that the scope of the present techniques and technologies are not limited by this detailed description. The present techniques and technologies may be embodied in other specific forms without departing from the spirit or essential characteristics thereof. Accordingly, the disclosure of the present techniques and technologies is intended to be illustrative and not limiting. Therefore, the spirit and scope of the appended claims should not be limited to the foregoing description. In U.S. applications, only those claims specifically reciting “means for” or “step for” should be construed in the manner required under 35 U.S.C. §112(f).

What is claimed is:

1. A caddy for housing a storage drive, the caddy comprising a caddy body to support the storage drive, the caddy body comprising:
a crossmember, the crossmember including:
a first and second grip on opposing sides of the crossmember;
a stopping edge; and
first and second guiding sides extending from the crossmember to connect to the storage drive, each of the first and second guiding sides having a first and second width, respectively, and at least one guiding side including one or more mounting pins for engaging with a cavity in the storage drive; and
wherein the stopping edge extends from at least one edge of one of the first or second guiding sides and the stopping edge extension is placed at a predetermined distance to determine the location of a housed storage drive.

2. The caddy of claim 1, wherein the first and second widths are different.

3. The caddy of claim 1, wherein the caddy body is unitary.

4. The caddy of claim 1, wherein the caddy body consists essentially of plastic.

5. The caddy of claim 1, further comprising one or more unitary handles, the handle including flexible members with pins fixed to the end, and wherein the caddy body further comprises:
a handle receptacle in the crossmember defined by two sidewalls;
a pivot point defined by two holes in each sidewall such that when the flexible members are retracted, the pins align with the holes and, when the flexible members are released, the handle is secured in place allowing the handle to be urged open or depressed closed, pivoting at the pivot point.

6. The caddy of claim 5, wherein a cutout on an edge of the handle allows for the handle to be easily accessed and extended from a closed position.

7. A guideway operable with a top-loading caddy having a first guide with a first width and a second guide with a second width, the guideway comprising:
an elongated body extending along a longitudinal axis, the elongated body having a top surface, a bottom surface, a first side, and a second side opposite the first side;
a plurality of first notches formed in the first side of the elongated body, each first notch of the plurality of notches extending transversely from the top surface to the bottom surface and being spaced apart along the longitudinal axis, wherein each notch defines a first contour visible in a top view or a bottom view of the elongated body, and wherein each first notch is configured to engage with the first guide, the first contour of each first notch being shaped to receive the first guide; and
a plurality of second notches formed in the second side of the elongated body, each second notch of the plurality of notches extending transversely from the top surface to the bottom surface and being spaced apart along the longitudinal axis, each second notch being aligned with a respective first notch of the plurality of first notches, wherein each second notch defines a second contour visible in a top view or a bottom view of the elongated body, and wherein each second notch is configured to engage with the second guide, the second contour of each second notch being shaped to receive the second guide.

8. The guideway of claim 7, wherein the contour of each notch of the plurality of notches is generally rectangular with filleted corners.

9. The guideway of claim 7, further comprising a first mounting apparatus on a first end of the guideway and a second mounting apparatus on a second end of the guideway.

10. The guideway of claim 7, wherein the first width is unequal to the second width.

11. The guideway of claim 7, wherein:
the elongated body is formed from a sheet of metallic material bent along the longitudinal axis to define a C-shaped cross-section, the C-shaped cross-section comprising a central web portion connecting two opposing flange portions, wherein the top surface and the bottom surface are defined by upper and lower edges of the central web portion and the two opposing flange portions, respectively;
the first side is defined by outer edges of the two opposing flange portions, the plurality of first notches being formed along the outer edges of the two opposing flange portions;
the second side is defined by the central web portion further comprising a plurality of cutouts formed through the central web portion and the two opposing flange portions, each cutout being aligned with a respective first notch of the plurality of notches, each bent cutout forming one of the plurality of second notches, the second contour of each second notch defined by a portion of the respective cutout formed in one of the two opposing flange portions.

12. A guideway assembly comprising a plurality of the caddy of claim 1 and two or more of the guideway of claim 7.

13. The guideway assembly of claim 12 including a first guideway and a second guideway parallel to each other and having the first and second plurality of notches of each of the first and second guideways aligned, separated by a distance allowing for a caddy to be inserted into the guideway assembly such that the first guiding side of the caddy engages with one of the first plurality of channels of the first guideway and the second guiding side of the caddy engages with an aligned one of the second plurality of channels of the second guideway.

14. The guideway assembly of claim 13, further comprising a third guideway aligned vertically with the first guideway and a fourth guideway aligned vertically with the second guideway, the third and fourth guideways parallel to each other and having the first and second plurality of notches of each of the third and fourth guideways aligned, separated by a distance allowing for a caddy to be inserted into the guideway assembly such that the first guiding side of the caddy engages with one of the first plurality of channels formed in the first and third guideways and the second guiding side of the caddy engages with an aligned one of the second plurality of channels formed in the second and fourth guideways.

15. The guideway assembly of claim 12, wherein the plurality of caddies are inserted between the two or more guideways, the stopping edge of each of the plurality of caddies resting on the top surface of one or more guideways.

16. The guideway assembly of claim 12, wherein the first contour of each guideway is a different width than the second contour of the guideway.

17. The guideway assembly of claim 13, further comprising a plurality of additional guideways, each additional guideway aligned with the first and second guideways, each additional guideway allowing for an additional row of caddies to be added to the guideway assembly.

18. The guideway assembly of claim 14, further comprising a server drawer including a first and second sidewall, a first end of each guideway affixed to the first sidewall, a second end of each guideway affixed to the second sidewall, all four guideways providing structural support to the server drawer and providing lateral positioning for each caddy, the first and second guideways bearing the load of the caddies.
